(19) United States
(12) Patent Application Publication
(10) Pub. No.: US 2007/0211542 A1
(43) Pub. Date: Sep. 13, 2007

(54) Multi-probe for writing and reading data and method of operating the same

(75) Inventors: Hyoung-soo Ko, Seoul (KR); Seung-bum Hong, Seongnam-si (KR); Dong-ki Min, Seoul (KR); Hong-sik Park, Seoul (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/604,263

(22) Filed: Nov. 27, 2006

(30) Foreign Application Priority Data
Nov. 25, 2005 (KR) 10-2005-0113571

(51) Int. Cl. G11C 7/10

(52) U.S. Cl. 365/189.01; 365/217

(57) ABSTRACT

A multi-probe for writing data to and/or reading data from a recording medium. The multi-probe includes a plurality of probes. All of the probes are working probes for writing the data to and/or reading the data from the recording medium.

### CROSS-REFERENCE TO RELATED PATENT APPLICATION

This application claims priority from Korean Patent Application No. 10-2005-0113571, filed on Nov. 25, 2005, in the Korean Intellectual Property Office, the disclosure of which is incorporated herein in its entirety by reference.

### BACKGROUND OF THE INVENTION

1. Field of the Invention

An apparatus and method consistent with the present invention relate to reading and writing data, and more particularly, to a multi-probe for writing and reading data and a method of operating the multi-probe.

2. Description of the Related Art

Along with the development of information technology, portable information devices and memory devices are widely used. Therefore, as a wide range of information is produced, there is a need to systematically classify and store the information in order to maximize the information utilizing efficiency. To fulfill this need, high-density data storage media and data reading/writing devices suitable for the high-density data storage media have been developed.

In recent years, a high-density data storage medium having a ferromagnetic layer or a ferroelectric layer has been proposed. Since the ferromagnetic layer and ferroelectric layers have, respectively, a residual magnetic polarization and a residual electric polarization, the data recorded on the recording medium having one of the ferromagnetic and ferroelectric layers are not deleted even when the electric power is turned off.

Reading the data from the recording medium having the ferroelectric layer involves a process that reads the electric charges distributed on a surface of the recording medium. A probe is widely used to read the data from the recording medium. The probe is also used to write the data to the recording medium.

In the following description, the recording medium is a recording medium having the ferroelectric layer. However, the recording medium of the present invention is not limited to just this embodiment.

In reading the data from the recording medium, a probe generates a data signal corresponding to an electric charge distribution on the surface of the recording medium. However, since the bit size of the recording medium is small, the intensity of the data signal generated from the probe is relatively low. Therefore, the data signal generated from the probe must be amplified using an amplification process.

The probe also generates a carrier signal (offset signal) having an intensity higher than that of the data signal. Accordingly, the carrier signal is also amplified together with the data signal during the amplification process. Therefore, the amplifying efficiency of the data signal is lowered.

FIG. 1 is a schematic view of a probe accessing a ferroelectric recording medium and an associated graph that plots a variation of a signal (G1) detected by the probe as it accesses a region on the recording medium.

Referring to the graph of FIG. 1, when a probe 10 accesses a recording medium 12 while moving in, for example, a direction denoted by the arrow, a signal current Id is generated by the probe 10. The current Id is a sum of a first current Ics and a first signal current Is1 or a sum of the first current Ics and a second signal current Is2. The first current Ics corresponds to a carrier signal, and the first signal current Is1 corresponds to a data signal that is generated by the probe when the probe 10 accesses a region where a direction of residual polarization is upward (↑). The second signal current Is2 corresponds to a data signal that is generated by the probe when the probe 10 accesses a region where a direction of residual polarization is downward (↓). When the first and second signal currents Is1 and Is2, respectively, are compared with the first current Ics, it is clear that an intensity of the first current Ics is greater than the intensities of the first and second signal currents Is1 and Is2.

Since the carrier signal and the data signal are summed, the carrier signal is also amplified during the amplifying process of the data signal. As a result, the amplification effect of the data signal is relatively reduced.

Therefore, a method has been developed that removes the carrier signal from the signal generated by the probe before the data signal is amplified.

FIG. 2 shows an example of such a method.

Referring to FIG. 2, a probe 20 includes a working probe 20a that accesses a recording medium on which data are recorded and a reference probe 20b that accesses a recording medium on which data are not recorded (or a region on which data are not recorded). A signal generated by the working probe 20a includes both data and carrier signals while a signal generated by the reference probe 20b includes only the carrier signal. Therefore, when the signal (i.e., a current IdB) generated by reference probe 20b is subtracted from the signal (i.e., a current IdA) generated by the working probe 20a, only a data signal current (IdA-IdB) corresponding to the data signal is obtained as shown in curve G2 of the graph of FIG. 2.

As described above, by using both the working probe 20a and the reference probe 20b, it is possible to extract only the data signal from the signal generated by the working probe 20a. As a result, only the data signal is amplified during the subsequent amplification process.

FIGS. 3 and 4 show related art multi-probes 28 and 48, respectively, which include working probes and reference probes.

The related art multi-probe 28 of FIG. 3 includes a plurality of working probes 30 that are arranged in a lattice pattern and a reference probe 40 that is commonly connected to the plurality of probes 30.

The related art multi-probe 28 of FIG. 3 can be manufactured through a simple process. However, it is difficult to obtain working probes 30 that are all uniform. Non-uniformity of the working probes 30 causes the multi-probe to malfunction.

The related art multi-probe 48 of FIG. 4 includes a plurality of probe groups 50 that are arranged in a lattice pattern. Each probe group 50 includes a working probe 50a and a reference probe 50b.

In the conventional multi-probe 48 of FIG. 4, the number of the working probes 50a is identical to that of the reference probes 50b. Therefore, a malfunction due to the non-uniformity between the working probes 50a does not occur. However, since the probe groups 50 are arranged in the lattice pattern, complications in the manufacturing process are inevitable.

Also, since the number of the probes of the multi-probe 48 of FIG. 4 is twice that of the probes of the multi-probe 28 of FIG. 3, the yield may be lower. In addition, since the reference probes 50b require an operating region, the region in which data is recorded may be reduced.

### SUMMARY OF THE INVENTION

Exemplary embodiments of the present invention overcome the above disadvantages and other disadvantages not described above.

The present invention provides a multi-probe that is not affected by non-uniformity between probes, is manufactured using a simple process and solves the problem of a reduction in the data recording region as well as the reduction in the yield.

The present invention also provides a method of operating the multi-probe.

According to an aspect of the present invention, there is provided a multi-probe for writing data to and/or reading data from a recording medium, the multi-probe including: a plurality of probes, wherein all of the probes are configured as working probes that write data to and/or read data from the recording medium.

The probes that are in a state where the probes are not accessing the recording medium, i.e., a stand-by state, may be used as reference probes for the probes that are accessing the recording medium.

The reference probe may be a firstly adjacent (i.e., immediately adjacent) probe to the working probe accessing the recording medium. However, the present invention is not limited to just this configuration and the reference probe may be, for example, a secondly adjacent probe to the working probe accessing the recording medium.

All of the probes may be arranged in a lattice pattern.

According to another aspect of the present invention, there is provided a method of operating a multi-probe having a plurality of working probes for writing data to and/or reading data from the recording medium, the method including: allowing a first working probe comprising at least one working probe from among the plurality of the working probes to access the recording medium while using a second working probe comprising at least one working probe from among the plurality of the working probes to be in a stand-by state with respect to accessing the recording medium. The second working probe may comprise at least one working probe that functions as a reference probe for the first working probe.

The at least one working probe of the second working probe may be a firstly adjacent working probe to the at least one working probe in the first working probe or a secondly adjacent working probe from the at least one working probe in the first working probe.

The first working probe may comprise at least two working probes from among the plurality of the working probes, and the second working probe may comprise the same number of working probes as the first working probe.

Accordingly, a multi-probe consistent with the present invention does not necessarily include a reference probe but may only include working probes arranged in a lattice pattern. Therefore, the present invention can simplify the manufacturing process and prevent a data recording area from being reduced due to the existence of the reference probe. In addition, since an adjacent working probe is used as the reference probe, the multi-probe of the present invention is not affected by the non-uniformity between the working probes.

### BRIEF DESCRIPTION OF THE DRAWINGS

The above and other aspects of the present invention will become more apparent by describing in detail exemplary embodiments thereof with reference to the attached drawings in which:

FIG. 1 is a schematic view of a probe accessing a ferroelectric recording medium, and also illustrates an associated graph that plots a variation of a signal detected by the probe as it accesses a region on the recording medium;

FIG. 2 is a schematic view of a probe that accesses a ferroelectric recording medium and removes a carrier signal (a offset signal) and also illustrates an associated graph that plots a variation of a signal detected by the working and reference probes concurrently as the probe accesses the recording medium;

FIGS. 3 and 4 are top views of related art multi-probes each including working and reference probes;

FIG. 5 is a schematic view of a basic concept of a multi-probe and an operation of the multi-probe according to an exemplary embodiment of the present invention;

FIG. 6 is a schematic view of a multi-probe according to an exemplary embodiment of the present invention; and

FIG. 7 is a schematic view of a multi-probe according to another exemplary embodiment of the present invention.

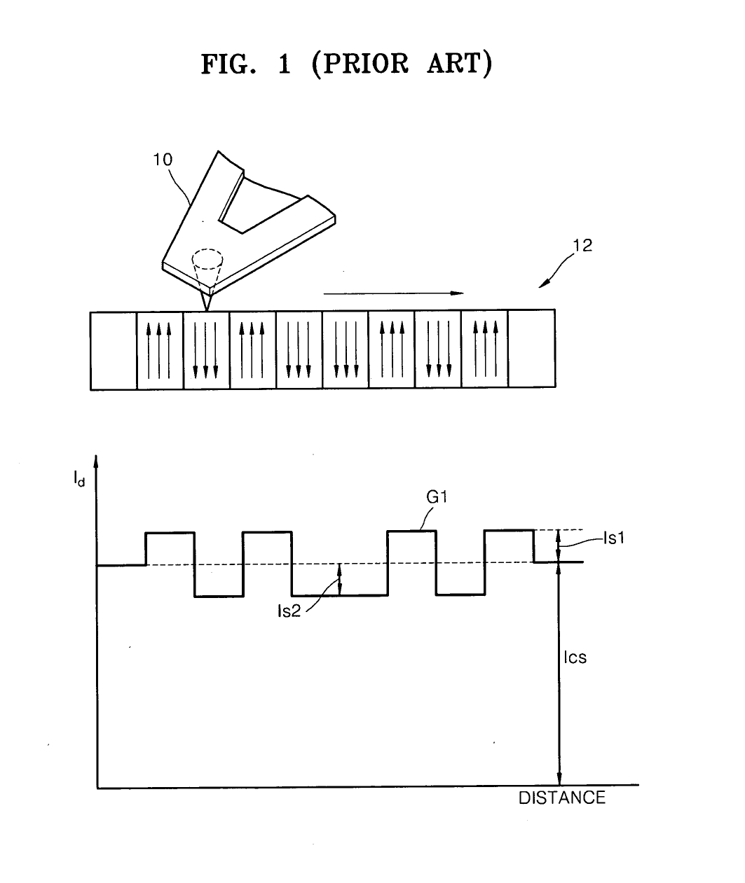

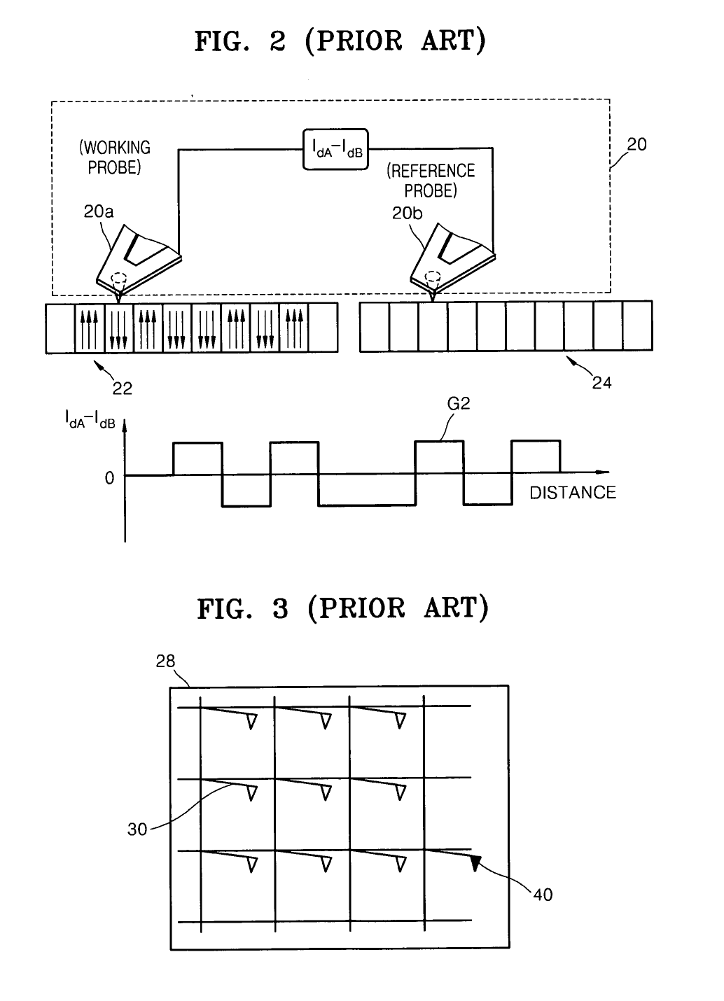

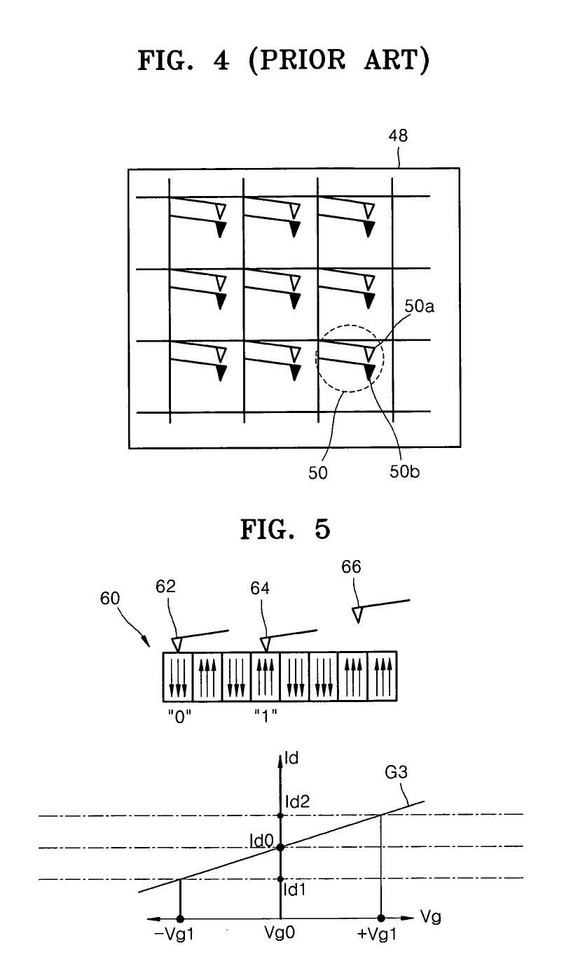

### DETAILED DESCRIPTION OF EXEMPLARY EMBODIMENTS OF THE INVENTION

The present invention will now be described more fully with reference to the accompanying drawings, in which exemplary embodiments of the invention are shown. In the drawings, the thicknesses of layers and regions are exaggerated for clarity.

FIG. 5 is a schematic view of a basic concept of a multi-probe and an operation of the multi-probe according to an exemplary embodiment of the present invention;

Referring to FIG. 5, first and second working probes 62 and 64 access a recording medium 60 while a third working probe 66 is set in a stand-by state with respect to accessing the recording medium 60. The first through third working probes 62, 64 and 66 are parts of a plurality of probes included in the inventive multi-probe. The first working probe 62 accesses a region where a direction of the residual polarization is downward (↓), e.g., a region where a bit data 0 is recorded. Due to the downward residual polarization, an electric potential difference −Vg1 is formed between a top surface and a bottom surface of this region. The second working probe 64 accesses a region where a direction of the residual polarization is upward (↑), e.g., a region where a bit data 1 is recorded. Due to the upward residual polarization, an electric potential difference +Vg1 is formed between a top surface and a bottom surface of this region. In the recording medium, an absolute value of the electric potential difference between the top and bottom surfaces of the region where the direction of the residual polarization is upward (↑) is same as that of the electric potential difference between the top and bottom surfaces of the region where the direction of the residual polarization is downward (↓). However, the electric charges distributed on the top surfaces of these regions have polarities that are opposite to each other due to the directions of the respective residual polarizations. Therefore, for convenience, the electric potential difference between the top and bottom surfaces of the region accessed by the first working probe 62 is assigned a negative sign (−) while the electric potential difference between the top and bottom surfaces of the region accessed by the second working probe 64 is assigned a positive sign (+).

Referring to curve G3 of the graph of FIG. 5, the voltage Vg (x-coordinate) represents the electric potential difference between the top and bottom surfaces of the recording medium 60 due to the existence of the residual polarization. For example, the electric potential difference between the top and bottom surfaces of a region accessed by the first working probe 62 is plotted as −Vg1 on curve G3, and the electric potential difference between the top and bottom surfaces of a region accessed by the second working probe 64 is plotted as +Vg1 on curve G3. Since the electric potential differences −Vg1 and +Vg1 have the same absolute values, they are positioned at equal distances from the y-coordinate axis.

As described above, −Vg1 represents the electric potential difference between the top and bottom surfaces of the region accessed by the first working probe 62, i.e., the bit data corresponding to a 0. When the voltage Vg is the electron potential difference −Vg1, a first current Id1 generated by, for example, the first working probe 62 represents a data signal current corresponding to the bit data 0 and a carrier signal current. A second current Id2 measured when the voltage Vg is the electric potential difference +Vg1 represents a data signal current corresponding to the bit data 1 and a carrier signal current.

In the example illustrated in FIG. 5, the third working probe 66 is in a state where it is not accessing the recording media 60, i.e., a stand-by state. The stand-by state is identical to a case where a working probe accesses a region of the recording medium that does not have a residual polarization. Because the electric potential difference between the top and bottom surfaces of a region of the recording medium not having a residual polarization is 0, Vg0, which equals 0 on curve G3 of the graph of FIG. 5, represents the electric potential between the top and bottom surfaces of a region of the recording medium 60 not having a residual polarization. However, since, in the example, there is no region on recording medium 60 where residual polarization does not exist, Vg0 corresponds to a working probe in a stand-by state, e.g., the third working probe 66. Therefore, a current Id0 measured when the voltage Vg is Vg0 corresponds to a signal current generated from the third working probe 66 that is in a stand-by state with respect to accessing the recording medium. Since the third working probe 66 is in a state where it is not accessing the recording media 60, a bit data signal current is not included in the signal current Id0. That is, the signal current Id1 includes only the carrier signal current. Therefore, the third working probe 66 can be used as a reference probe until the third working probe 66 accesses the recording medium 60. Specifically, the third working probe 66 may be used as a reference probe for an adjacent working probe that is accessing the recording medium 60.

For example, assuming that the first working probe 62 is a working probe that is adjacent to the third working probe 66, the third working probe 66 may be used as a reference probe for the first working probe 62 until the third working probe 66 accesses the recording medium 60. Therefore, after the signal current Id1 is measured through the first working probe 62, the signal current Id0 that is measured through the third working probe 66 is subtracted from the signal current Id1 (hereinafter, first calculation). By this first calculation, since the carrier signal current is removed from the signal current Id1, the modified signal current Id1 includes only the data signal current corresponding to the bit data 0. This result is identical to a case where the curve G3 of the graph of FIG. 5 is shifted downward along the y-coordinate until the signal current Id0 becomes 0. After the first calculation is performed, the signal current Id1 may be amplified.

Assuming that the second working probe 64 is a working probe that is adjacent to the third working probe 66, the third working probe 66 may be used as a reference probe for the second working probe 64 until the third working probe 66 accesses the recording medium 60. Therefore, after the signal current Id2 is measured through the second working probe 64, the signal current Id0 that is measured through the third working probe 66 may be subtracted from the signal current Id2 (hereinafter, second calculation). By this second calculation, since the carrier signal current is removed from the signal current Id2, the signal current Id2 includes only the data signal current corresponding to the bit data 1. This result is identical to a case where the curve G3 of the graph of FIG. 5 is moved downward along the y-coordinate until the signal current Id0 becomes 0. After the second calculation is performed, the signal current Id2 may be amplified.

When the third working probe 66 accesses the recording medium 60, an adjacent working probe (not shown) is in a stand-by state with respect to accessing the recording medium 60, and the adjacent working probe may be used as a reference probe for the third working probe 66 until the adjacent probe accesses the recording medium 60.

A multi-probe according to an exemplary embodiment of the present invention and an operation thereof will now be described.

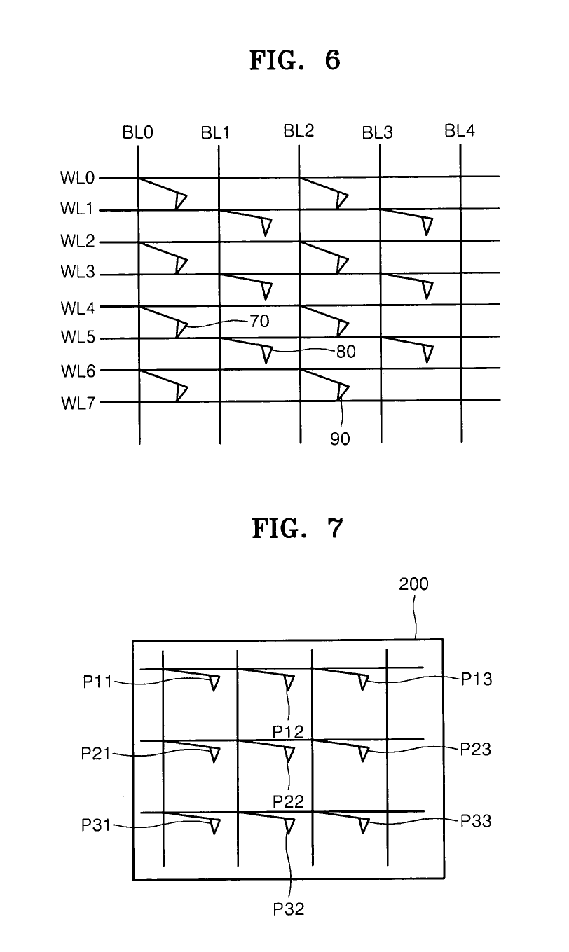

Referring to FIG. 6, working probes are located, for example, at first regions where even number rows WL0, WL2, WL4, . . . intersect even number columns BL0, BL2, BL4, . . . and at second regions where odd number rows WL1, WL3, . . . intersect odd number columns BL1, BL3, . . . . The working probes 70 located at the first regions are paired with the respective adjacent working probes 80 located at the second regions. When the working probe 70 accesses the recording medium, the adjacent working probe 80 is in a stand-by state where it is not accessing the recording medium. The adjacent working probe 80 functions as a reference probe for the working probe 70, thereby allowing the calculation operation described above to be performed. When the working probe 80 located at the second region accesses the recording medium, the working probe 90 at the first region adjacent to the working probe 80 is in a stand-by state, and the working probe 90 functions as a reference probe for the working probe 80. This relationship is applied to all of the working probes placed at the first and second regions.

A multi-probe according to another embodiment of the present invention and an operation thereof will now be described.

Referring to FIG. 7, a multi-probe 200 of this embodiment includes a plurality of working probes P11, P12, P13, P21, P22, P23, P31, P32, and P33 arranged in a lattice pattern. One working probe is placed at each lattice. The multi-probe 200 does not include any reference probes. Although only nine working probes are shown in FIG. 7 for convenience, the multi-probe 200 may include more than nine working probes or less than nine working probes.

The operation of the multi-probe 200 of FIG. 7 will now be described. When one of the working probes, e.g., the working probe P21 located in the second row of the first column, accesses the recording medium, an adjacent working probe, e.g., working probe P22 located in the second row of the second column and adjacent to the working probe P21, that is in a stand-by state may be used as a reference probe for the working probe accessing the recording medium. Therefore, in our example, a signal current generated by the working probe P21 can be modified to leave only the data signal current. When the working probe P22, which was used as the reference probe, starts accessing the recording medium, the working probe P33 (in the third row of the third column) adjacent to the working probe P22 and in a stand-by state may be used as a reference probe for the working probe P22.

There may be both working probes and reference probes among the working probes placed along a same column. For example, when the working probe P12 among the three working probes P12, P22 and P32 that are located along the second column accesses the recording medium, the adjacent working probe P22 can be used as a reference probe for the working probe P12.

Alternatively, the secondly adjacent working probe instead of the firstly adjacent working probe may be used as the reference probe for the accessing working probe.

For example, when the working probe P11 located in the first row of the first column accesses the recording medium, the reference probe for the working probe P11 may not necessarily be the firstly adjacent working probe P21 or P12, but, instead, may be the secondly adjacent working probe P22.

The above-described operation can be applied even when more than two working probes simultaneously access the recording medium.

For example, when the working probe P11 located in the first row of the first column and the working probe P21 located in the second row of the first column access simultaneously the recording medium, the working probe P12 located in the first row of the second column or the working probe P22 located in the second row of the second column may be used as the reference probe for the working probe P11, and the working probe P31 located in the third row of the first column or the working probe P32 located in the third row of the second column may be used as the reference probe for the working probe P21. When the working probe P22 is used as the reference probe for the working probe P11, another stand-by working probe, e.g., working probe P31 or P32, is used as the reference probe for the working probe P21 in order to prevent the same stand-by working probe from being commonly used as the reference probe for more than one working probe accessing the recording medium.

According to the exemplary embodiments of the present invention, the multi-probe of the present invention does not necessarily include a reference probe but may only include working probes arranged in a lattice pattern. Therefore, the present invention can simplify the manufacturing process and prevent a data recording area from being reduced due to the existence of a reference probe. In addition, since an adjacent working probe is used as the reference probe, the multi-probe of the present invention is not affected by the non-uniformity between the working probes.

While the present invention has been particularly shown and described with reference to exemplary embodiments thereof, it will be understood by those of ordinary skill in the art that various changes in form and details may be made therein without departing from the spirit and scope of the present invention as defined by the following claims.

For example, the probes may be arranged in a lattice pattern in which each block has vertical and horizontal sides with different lengths.

In addition, the resistance of the working probes in the above exemplary embodiments are the same. However, the resistance of the working probes may be different from each other as long as the probes perform identical functions.

What is claimed is:

1. A multi-probe for writing data to or reading data from a recording medium, the multi-probe comprising:
a plurality of probes, wherein each of the plurality of probes is configured as a working probe that writes the data to or reads the data from the recording medium, and at least one probe of the plurality of probes is configured as a reference probe to adjust a data signal generated by at least one other probe of the plurality of probes.

2. The multi-probe of claim 1, wherein the at least one probe of the plurality of probes that is configured as the reference probe is in a state of not accessing the recoding medium.

3. The multi-probe of claim 2, wherein the reference probe is a firstly adjacent probe to a working probe accessing the recording medium.

4. The multi-probe of claim 2, wherein the reference probe is a secondly adjacent probe to a working probe accessing the recording medium.

5. The multi-probe of claim 1, wherein the plurality of probes are arranged in a lattice pattern.

6. A method of operating a multi-probe comprising a plurality of working probes for writing data to or reading data from a recording medium, the method comprising:
allowing a first working probe comprising at least one working probe from among the plurality of the working probes to access the recording medium while using a second working probe comprising at least one working probe from among the plurality of the working probes as a reference probe for the first working probe,
wherein the at least one working probe of the second working probe is in a state of not accessing the recording medium, and
wherein each of the first working probe and the second working probe is configured to write data to or read data from the recording medium.

7. The method of claim 6, wherein the at least one working probe of the second working probe is a firstly adjacent working probe to the at least one working probe of the first working probe or a secondly adjacent working probe to the at least one working probe of the first working probe.

8. The method of claim 6, wherein the first working probe comprises at least two working probes from the plurality of the working probes, and the second working probe comprises at least two working probes from the plurality of working probes.

9. The method of claim 8, wherein the second working probe comprises a same number of working probes as the first working probe.
